(19) United States
(12) Patent Application Publication
(10) Pub. No.: US 2026/0324462 A1
(43) Pub. Date: Oct. 15, 2026

(54) CIRCUIT BOARD, AND SEMICONDUCTOR PACKAGE COMPRISING SAME

(71) Applicant: LG INNOTEK CO., LTD., Seoul (KR)

(72) Inventors: Soo Min LEE, Seoul (KR); Woo Seop SIM, Seoul (KR); Jong Heun YOO, Seoul (KR)

(73) Assignee: LG INNOTEK CO., LTD., Seoul (KR)

(21) Appl. No.: 19/117,337

(22) PCT Filed: Oct. 4, 2023
(86) PCT No.: PCT/KR2023/015221

§ 371 Date: Mar. 31, 2025

(30) Foreign Application Priority Data
Sep. 29, 2022 (KR) 10-2022-0124641

(51) Int. Cl. H10W 70/63; H10W 70/654; H10W 90/00; H10W 90/10; H10W 90/28

(52) U.S. Cl. CPC H10W 70/63; H10W 70/654; H10W 90/10; H10W 90/28; H10W 90/401; H10W 90/722; H10W 90/724

(57) ABSTRACT

A semiconductor package according to an embodiment includes an insulating layer; a plurality of electrode parts including a through part penetrating from an upper surface of the insulating layer to a partial region of the insulating layer; and a connection member embedded in the insulating layer; wherein the plurality of electrode parts include a first electrode part including a first through part overlapping the connection member in a vertical direction, and a second electrode part including a second through part that does not overlap the connection member in the vertical direction, and a size of the first through part satisfies a range of 80% to 100% of a size of the second through part.

### TECHNICAL FIELD

An embodiment relates to a circuit board, and more particularly, to a circuit board capable of resolving height deviation of a plurality of through electrodes connected to semiconductor devices, and a semiconductor package including the same.

### BACKGROUND ART

As performances of electric/electronic products progresses, technologies for disposing a greater number of semiconductor devices on a semiconductor package substrate of a limited size are being proposed and studied. However, since a general semiconductor package is based on mounting a single semiconductor device, there is a limit to obtaining a desired performance.

Accordingly, a semiconductor package that mounts a plurality of semiconductor devices using a plurality of circuit boards has been recently provided. This semiconductor package has a structure in which a plurality of semiconductor devices are connected to each other in a horizontal direction and/or a vertical direction on the circuit board. Accordingly, the semiconductor package has the advantage of efficiently using a mounting area of the semiconductor devices and transmitting high-speed signals through a short signal transmission path between the semiconductor devices.

Due to these advantages, the semiconductor package as described above is widely applied to mobile devices, etc.

In addition, semiconductor packages applied to products that provide the Internet of Things (IoT), autonomous vehicles, and high-performance servers are expanding a concept to semiconductor chiplets as a number of semiconductor devices and/or a size of each semiconductor device increases in accordance with a trend of high integration, or as functional parts of the semiconductor devices are divided.

Accordingly, an intercommunication between semiconductor devices and/or semiconductor chiplets is becoming important, and accordingly, there is a trend to dispose an interposer between the circuit board of the semiconductor package and the semiconductor devices.

An interposer can function as a redistribution layer that gradually increases a width or depth of a circuit pattern from the semiconductor device to the semiconductor package in order to facilitate the intercommunication between the semiconductor devices and/or semiconductor chiplets, or to interconnect the semiconductor devices and the semiconductor package substrate, thereby smoothly transmitting electrical signals between the semiconductor device and the semiconductor package substrate having a relatively large circuit pattern compared to the circuit pattern of the semiconductor device.

Meanwhile, a package substrate and/or interposer applied to a semiconductor package is provided with a connection member connected to a semiconductor device and/or a semiconductor chip-let. The connection member functions to horizontally connect a plurality of semiconductor devices and/or semiconductor chip-lets. Accordingly, the connection member may be embedded in the package circuit board and/or interposer. At this time, the package substrate and/or the interposer are provided with a plurality of through electrodes connected to the semiconductor device and/or the semiconductor chiplet. The through electrodes include a first through electrode that overlaps the connecting member in a vertical direction, and a second through electrode that overlaps the first through electrode in a horizontal direction while not overlapping the connecting member in the vertical direction.

At this time, the first through electrode is connected to a connection member. Accordingly, a width and/or thickness of the first through electrode can be determined by a width of a connection electrode provided in the connection member and a thickness of the connection member. Accordingly, the first through electrode and the second through electrode can have different widths and/or thicknesses.

As a result, the first through electrode and the second through electrode provided in the package substrate and/or the interposer can have different heights. For example, due to a difference in the width and/or thickness, a deviation may occur between a height of the first through electrode and a height of the second through electrode. In addition, when a height deviation occurs between the first and second through electrodes, a problem may occur in which the semiconductor device and/or semiconductor chiplet is not stably mounted, and thus, there may be a problem that operating characteristics of the semiconductor device and/or the semiconductor chiplet are deteriorated.

### DISCLOSURE

### Technical Problem

An embodiment provides a circuit board having a novel structure and a semiconductor package comprising the same.

In addition, the embodiment provides a circuit board having a connection member embedded therein and a semiconductor package comprising the same.

In addition, the embodiment provides a circuit board capable of controlling a height deviation between a plurality of through electrodes connected to a semiconductor device and a semiconductor package comprising the same.

In addition, the embodiment provides a circuit board having improved heat dissipation characteristics and a semiconductor package comprising the same.

In addition, the embodiment provides a circuit board having improved adhesion between a circuit board and the connection member and a semiconductor package comprising the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises an insulating layer; a plurality of electrode parts including a through part penetrating from an upper surface of the insulating layer to a partial region of the insulating layer; and a connection member embedded in the insulating layer; wherein the plurality of electrode parts include: a first electrode part including a first through part overlapping the connection member in a vertical direction, and a second electrode part including a second through part that does not overlap the connection member in the vertical direction, and wherein a size of the first through part satisfies a range of 80% to 100% of a size of the second through part.]

In addition, each of the first and second through parts is provided in a plurality of numbers, and a size of each of a plurality of first through parts satisfies a range of 80% to 100% of a size of each of a plurality of second through parts.

In addition, the plurality of first through parts overlap the plurality of second through parts in a horizontal direction.

In addition, a thicknesses of the first through part and the second through part in the vertical direction are same, and widths of the first through part and the second through part in a horizontal direction are same.

In addition, a thickness of the first through part in the vertical direction is smaller than a thickness of the second through part in the vertical direction, and a width of the first through part in a horizontal direction is greater than a width of the second through part in the horizontal direction.

In addition, a thickness of the first through part in the vertical direction is greater than a thickness of the second through part in the vertical direction, and a width of the first through part in a horizontal direction is smaller than a width of the second through part in the horizontal direction.

In addition, at least one of a density and a volume of the first through part satisfies a range of 80% to 100% of at least one of a density and a volume of the second through part.

In addition, the first electrode part includes a first protruding part disposed on the first through part and protruding on the insulating layer, and the second electrode part includes a second protruding part disposed on the second through part and protruding on the insulating layer.

In addition, a height of an upper surface of the first protruding part is same as a height of an upper surface of the second protruding part.

In addition, a width of the first through part in a horizontal direction satisfies a range of 10 μm to 40 μm.

In addition, each of the first and second through parts has a slope whose width gradually decreases from an upper surface toward a lower surface.

In addition, each of the first through part and the second through part includes a first metal layer; and a second metal layer disposed on the first metal layer and including a metal material different from the first metal layer.

In addition, a lower surface of the first metal layer of each of the first and second through parts includes a convex portion recessed toward a lower surface of the insulating layer.

In addition, the semiconductor package further includes first and second semiconductor devices disposed on the first and second electrode parts, and the first electrode part includes first electrode parts of a first group connected to a terminal of the first semiconductor device and first electrode parts of a second group connected to a terminal of the second semiconductor device, and the second electrode part includes second electrode parts of a first group connected to a terminal of the first semiconductor device and second electrode parts of a second group connected to a terminal of the second semiconductor device.

In addition, the second through part of at least one of the second electrode parts of the first group and the second group includes a plurality of sub-through parts vertically overlapped with a single protruding part and horizontally spaced apart from each other.

In addition, an upper surface of the single protruding part that is vertically overlapped with the plurality of sub-through parts includes a concave portion recessed toward each of the plurality of sub-through parts.

### Advantageous Effects

The embodiment can minimize a height deviation of first and second electrode parts penetrating from an upper surface of the insulating layer to a partial region of the insulating layer while being connected to the semiconductor device.

Specifically, the first electrode part can be vertically overlapped with the connection member, and the second electrode part can be horizontally overlapped with the first electrode part without being vertically overlapped with the connection member. The first electrode part can include a first through part penetrating at least a part of the insulating layer and a first protruding part positioned on the first through part and protruding on the insulating layer. The second electrode part can include a second through part penetrating at least a part of the insulating layer and a second protruding part positioned on the second through part and protruding on the insulating layer. At this time, a size of the second through part can correspond to a size of the first through part. Preferably, a size of the second through part can satisfy a range of 80% to 100% of a size of the first through part. The embodiment can minimize a height deviation between the first electrode part and the second electrode part caused by a size difference between the first through part and the second through part, thereby allowing the semiconductor device to be stably disposed on the first and second electrode parts.

Preferably, a thickness of the first through part in a vertical direction can be same as a thickness of the second through part in the vertical direction, and a width of the first through part in a horizontal direction can be the same as a width of the second through part in the horizontal direction.

In addition, a thickness of the first through part in the vertical direction can be smaller than a thickness of the second through part in the vertical direction, and a width of the first through part in the horizontal direction can be larger than a width of the second through part in the horizontal direction.

In addition, a thickness of the first through part in the vertical direction can be larger than a thickness of the second through part in the vertical direction, and a width of the first through part in the horizontal direction can be smaller than a width of the second through part in the horizontal direction.

Accordingly, the embodiment can allow a height of the first electrode part and a height of the second electrode part to be uniform. The first and second semiconductor devices can be stably disposed. Therefore, the embodiment can improve operating characteristics of the first and second semiconductor devices. Furthermore, the embodiment can allow the first and second semiconductor devices to operate smoothly, and through this, the electronic product or server can operate smoothly.

In addition, the embodiment can prevent a change in impedance that occurs due to a change in the thickness of the first electrode part and the second electrode part by making the first electrode part and the second electrode part have a same height, thereby further improving the electrical reliability.

Meanwhile, the second through part of the second electrode part can include a plurality of sub-through parts that overlap each other vertically with one second pad part. In addition, a size of each of the plurality of sub-through parts can correspond to a size of the first through part. Accordingly, even if the second through part includes a plurality of sub-through parts, the first electrode part and the second electrode part can have a uniform height. In addition, a concave portion can be provided at an upper surface of the second protruding part that vertically overlaps the plurality of sub-through parts. In addition, a conductive adhesive material such as solder can be stably settled on the concave portion provided in the second protruding part. For example, the concave portion of the second protruding part can serve as a dam function that prevents movement of a solder while guiding a settlement position where the solder is settled. Furthermore, the embodiment can improve heat dissipation characteristics of the semiconductor package by allowing heat to be transferred through the plurality of sub-through parts, and can further improve the operating characteristics of the semiconductor package.

Furthermore, the embodiment can prevent a change in impedance caused by a decrease in the width of the second through part since the second through part includes a plurality of sub-through parts, and thereby improve operating characteristics of the first and second semiconductor devices. Furthermore, the embodiment can enable smooth operation of the first and second semiconductor devices, thereby enabling smooth operation of electronic products or servers.

### DESCRIPTION OF DRAWINGS

FIG. 1a is a cross-sectional view showing a semiconductor package according to a first embodiment.

FIG. 1b is a cross-sectional view showing a semiconductor package according to a second embodiment.

FIG. 1c is a cross-sectional view showing a semiconductor package according to a third embodiment.

FIG. 1d is a cross-sectional view showing a semiconductor package according to a fourth embodiment.

FIG. 1e is a cross-sectional view showing a semiconductor package according to a fifth embodiment.

FIG. 2 is a cross-sectional view showing a circuit board according to a first embodiment.

FIG. 3 is a plan view of the circuit board of FIG. 2 viewed from an upward direction.

FIG. 4 is an enlarged cross-sectional view of a first region R1 of FIG. 2.

FIG. 5 is a cross-sectional view showing a detailed layer structure of a first through electrode and a second through electrode of FIG. 2.

FIG. 6 is an enlarged cross-sectional view of a first region of FIG. 2 according to a second embodiment.

FIG. 7 is an enlarged cross-sectional view of a first region of FIG. 2 according to a third embodiment.

FIG. 8 is an enlarged cross-sectional view of a first region of FIG. 2 according to a fourth embodiment.

FIG. 9 is an enlarged cross-sectional view of a first region of FIG. 2 according to a fifth embodiment.

FIG. 10 is a cross-sectional view showing a circuit board according to a sixth embodiment.

### BEST MODE

Hereinafter, exemplary embodiments of the present invention will be described in detail with reference to the accompanying drawings, wherein like reference numerals are used to designate identical or similar elements, and redundant description thereof will be omitted. The suffix “module” and “portion” of the components used in the following description are only given or mixed in consideration of ease of preparation of the description, and there is no meaning or role to be distinguished as it is from one another. Also, in the following description of the embodiments of the present invention, a detailed description of related arts will be omitted when it is determined that the gist of the embodiments disclosed herein may be obscured. Also, the accompanying drawings are included to provide a further understanding of the invention, are incorporated in, and constitute a part of this description, and it should be understood that the invention is intended to cover all modifications, equivalents, or alternatives falling within the spirit and scope of the invention.

Terms including ordinals, such as first, second, etc., may be used to describe various components, but the elements are not limited to these terms. The terms are used only for distinguishing one component from another.

When a component is referred to as being “connected” or “contacted” to another component, it may be directly connected or joined to the other component, but it should be understood that other component may be present therebetween. When a component is referred to as being “directly connected” or “directly contacted” to another component, it should be understood that other component may not be present therebetween.

A singular representation includes plural representations, unless the context clearly implies otherwise.

In the present application, terms such as “including” or “having” are used to specify the presence of features, numbers, steps, operations, components, parts, or combinations thereof described in the description. However, it should be understood that the terms do not preclude the presence or addition of one or more other features, numbers, steps, operations, components, parts, or combinations thereof.

Hereinafter, embodiments of a present invention will be described in detail with reference to attached drawings.

### —Electronic Device—

Before describing the embodiment, an electronic device to which the semiconductor package of the embodiment is applied will be briefly described. The electronic device includes a main board (not shown). The main board may be physically and/or electrically connected to various components. For example, the main board may be connected to the semiconductor package of the embodiment. Various semiconductor devices may be mounted on the semiconductor package.

The semiconductor device may include an active device and/or a passive device. The active device may be a semiconductor chip in the form of an integrated circuit (IC) in which hundreds to millions of devices are integrated in one semiconductor device. The semiconductor device may be a logic chip, a memory chip, or the like. The logic chip may be a central processor (CPU), a graphics processor (GPU), or the like. For example, the logic chip may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far.

The memory chip may be a stack memory such as HBM. The memory chip may also include a memory chip such as volatile memory (e.g., DRAM), non-volatile memory (e.g., ROM), flash memory, and the like.

On the other hand, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

In addition, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

Hereinafter, a semiconductor package including a circuit board according to an embodiment will be described. The semiconductor package of the embodiment may have various package structures including a circuit board to be described later.

In addition, the circuit board in one embodiment may be a first circuit board described below.

In addition, the circuit board in another embodiment may be a second circuit board described below.

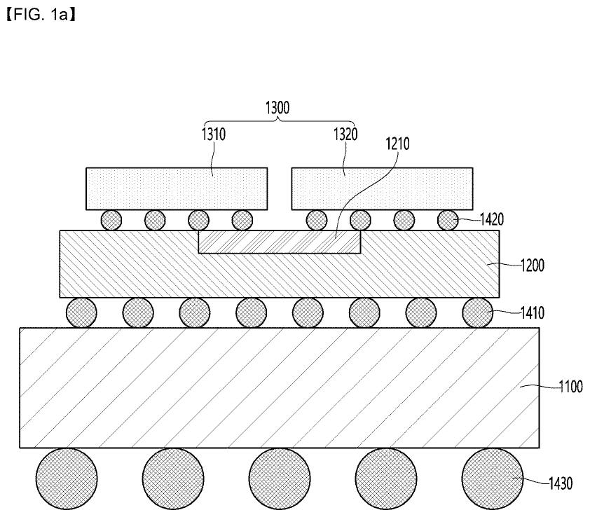

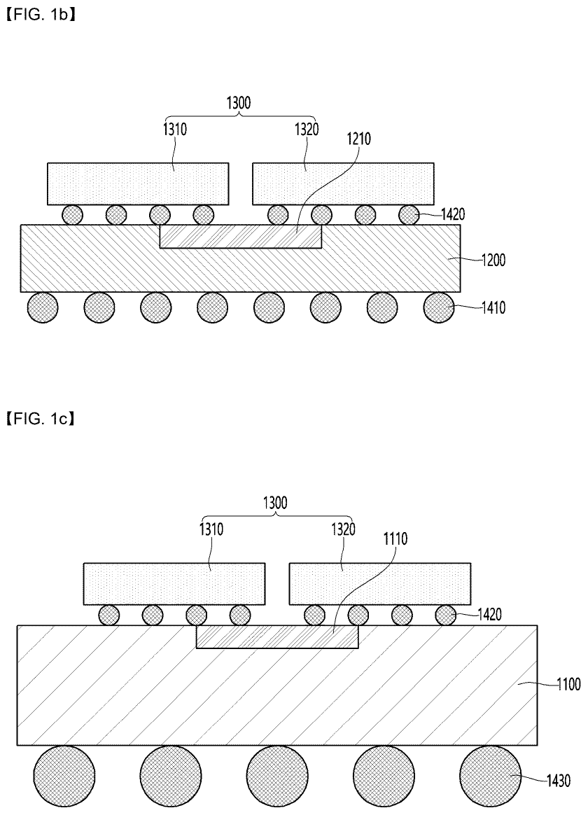

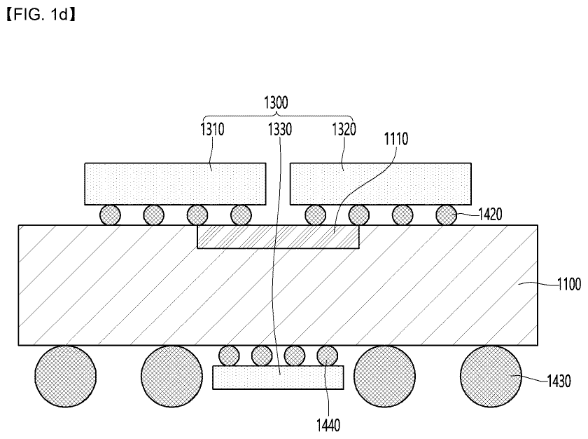

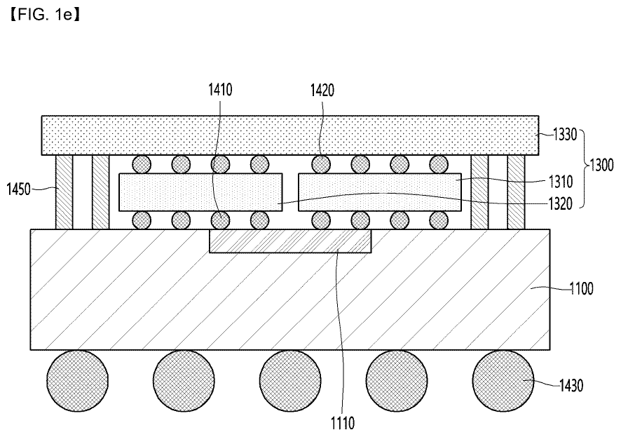

FIG. 1a is a cross-sectional view showing a semiconductor package according to a first embodiment, FIG. 1b is a cross-sectional view showing a semiconductor package according to a second embodiment, FIG. 1c is a cross-sectional view showing a semiconductor package according to a third embodiment, FIG. 1d is a cross-sectional view showing a semiconductor package according to a fourth embodiment, and FIG. 1e is a cross-sectional view showing a semiconductor package according to a fifth embodiment.

Referring to FIG. 1a, the semiconductor package according to the first embodiment may include a first circuit board 1100, a second circuit board 1200, and a semiconductor device 1300.

The first circuit board 1100 may mean a package circuit board.

For example, the first circuit board 1100 may provide a space to which at least one external circuit board is coupled. The external circuit board may refer to a second circuit board 1200 coupled to the first circuit board 1100. Also, the external circuit board may refer to a main board included in an electronic device coupled to a lower portion of the first circuit board 1100.

Also, although not shown in the drawing, the first circuit board 1100 may provide a space in which at least one semiconductor device is mounted.

The first circuit board 1100 may include at least one insulating layer, an electrode part disposed on the at least one insulating layer.

A second circuit board 1200 may be disposed on the first circuit board 1100.

The second circuit board 1200 may be an interposer. For example, the second circuit board 1200 may provide a space in which at least one semiconductor device is mounted. The second circuit board 1200 may be connected to the at least one semiconductor device 1300. For example, the second circuit board 1200 may provide a space in which the first semiconductor device 1310 and the second semiconductor device 1320 are mounted. The second circuit board 1200 may electrically connect the first and second semiconductor devices 1310 and 1320 and the first circuit board 1100 while electrically connecting the first semiconductor device 1310 and the second semiconductor device 1320. That is, the second circuit board 1200 may perform a horizontal connection function between a plurality of semiconductor devices and a vertical connection function between the semiconductor devices and the package circuit board.

FIG. 1a illustrates that the first and second semiconductor devices 1310 and 1320 are disposed on the second circuit board 1200, but is not limited thereto. For example, one semiconductor device may be disposed on the second circuit board 1200, or alternatively, three or more semiconductor devices may be disposed.

The second circuit board 1200 may be disposed between at least one semiconductor device 1300 and the first circuit board 1100.

In an embodiment, the second circuit board 1200 may be an active interposer that functions as a semiconductor device. When the second circuit board 1200 functions as a semiconductor device, the semiconductor package of the embodiment may have a structure that is vertically stacked on the first circuit board 1100 and may have functions of multiple logic chips. Having the function of a logic chip may mean that it may have functions of an active device and a passive device. In a case of an active device, characteristics of current and voltage may not be linear unlike a passive device, and in a case of an active interposer, it may have the function of an active device. In addition, the active interposer may perform a function of a corresponding logic chip while performing a signal transmission function between a second logic chip disposed thereon and the first circuit board 1100.

According to another embodiment, the second circuit board 1200 may be a passive interposer. For example, the second circuit board 1200 may function as a signal relay between the semiconductor device 1300 and the first circuit board 1100, and can have a passive device function such as a resistor, capacitor, or inductor. For example, a number of terminals of the semiconductor device 1300 is gradually increasing due to 5G, Internet of Things (IOT), increased image quality, and increased communication speed. That is, the number of terminals provided in the semiconductor device 1300 increases, thereby reducing the width of the terminals or an interval between the plurality of terminals. In this case, the first circuit board 1100 may be connected to the main board of the electronic device. There is a problem in that the thickness of the first circuit board 1100 increases or the layer structure of the first circuit board 1100 becomes complicated in order for the electrodes provided on the first circuit board 1100 to have a width and an interval to be respectively connected to the semiconductor device 1300 and the main board. Accordingly, in the first embodiment, the second circuit board 1200 may be disposed on the first circuit board 1100 and the semiconductor device 1300. In addition, the second circuit board 1200 may include electrodes having a fine width and an interval corresponding to the terminals of the semiconductor device 1300.

The semiconductor device 1300 may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far. The memory chip may be a stack memory such as HBM. The memory chip may also include a memory chip such as volatile memory (e.g., DRAM), non-volatile memory (e.g., ROM), flash memory, and the like.

Meanwhile, the semiconductor package of the first embodiment may include a connection part.

For example, the semiconductor package may include a first connection part 1410 disposed between the first circuit board 1100 and the second circuit board 1200. The first connection part 1410 may electrically connect the second circuit board 1200 to the first circuit board 1100 while coupling them.

For example, the semiconductor package may include the second connection part 1420 disposed between the second circuit board 1200 and the semiconductor device 1300. The second connection part 1420 may electrically connect the semiconductor device 1300 to the second circuit board 1200 while coupling them.

The semiconductor package may include a third connection part 1430 disposed on a lower surface of the first circuit board 1100. The third connection part 1430 may electrically connect the first circuit board 1100 to the main board while coupling them.

At this time, the first connection part 1410, the second connection part 1420, and the third connection part 1430 may electrically connect between the plurality of components by using at least one bonding method of wire bonding, solder bonding and metal-to-metal direct bonding. That is, since the first connection part 1410, the second connection part 1420, and the third connection part 1430 have a function of electrically connecting a plurality of components, when the metal-to-metal direct bonding is used, the connection part of the semiconductor package may be understood as an electrically connected portion, not a solder or wire.

The wire bonding method may refer to electrically connecting a plurality of components using a conductive wire such as gold (Au). Also, the solder bonding method may electrically connect a plurality of components using a material containing at least one of Sn, Ag, and Cu. In addition, the metal-to-metal direct bonding method may refer to recrystallization by applying heat and pressure between a plurality of components without the presence of solder, wire, conductive adhesive, etc. In addition, to directly bond between the plurality of components. In addition, the metal-to-metal direct bonding method may refer to a bonding method by the second connection part 1420. In this case, the second connection part 1420 may mean a metal layer formed between a plurality of components by the recrystallization.

Specifically, the first connection part 1410, the second connection part 1420, and the third connection part 1430 may couple a plurality of components to each other by a thermal compression (TC) bonding method. The thermal compression bonding may refer to a method of directly coupling a plurality of components by applying heat and pressure to the first connection part 1410, the second connection part 1420, and the third connection part 1430.

At this time, at least one of the first circuit board 1100 and the second circuit board 1200 may be provided with a protrusion that protrudes outwardly away from the insulating layer of the corresponding board, on which the first connection part 1410, the second connection part 1420, and the third connection part 1430 are disposed. The protrusion may protrude outwardly from the first circuit board 1100 or the second circuit board 1200.

The protrusion may be referred to as a bump. The protrusion may also be referred to as a post. The protrusion may also be referred to as a pillar. Preferably, the protrusion may refer to an electrode on which a second connection part 1420 for coupling with the semiconductor device 1300 is disposed among the electrodes of the second circuit board 1200. That is, as the pitch of the terminals of the semiconductor device 1300 becomes finer, a short circuit may occur between the plurality of second connection parts 1420 that are respectively connected to the plurality of terminals of the semiconductor device 1300 by a conductive adhesive such as a solder. Therefore, in the embodiment, thermal compression bonding may be performed to reduce a volume of the second connection part 1420. In addition, in order to secure diffusion prevention and alignment to prevent an intermetallic compound (IMC) formed between a conductive adhesive such as solder and a protrusion from diffusing into the interposer and/or the circuit board, a protrusion may be included in the electrode of the second circuit board 1200 on which the second connection part 1420 is disposed.

In addition, the semiconductor package may include a connection member 1210.

The connection member may be referred to as a bridge circuit board. For example, the connection member 1210 may include a redistribution layer. The connection member 1210 may perform a function of electrically connecting a plurality of semiconductor devices horizontally to each other. For example, since the area that a semiconductor device should generally have been too large, the connection member 1210 may include a redistribution layer. Since the semiconductor package and the semiconductor device have a large difference in a width or spacing of the circuit pattern, etc., a buffering role of the circuit pattern for electrical connection is required. The buffering role may mean having a size between a width or spacing of the circuit pattern of the semiconductor package and a width or spacing of the circuit pattern of the semiconductor device, and the redistribution layer may include a function of performing the buffering role.

In an embodiment, the connection member 1210 may be an inorganic bridge. For example, the inorganic bridge may include a silicon bridge. That is, the connection member 1210 may include a silicon substrate and a redistribution layer disposed on the silicon substrate.

In another embodiment, the connection member 1210 may be an organic material bridge. For example, the connection member 1210 may include an organic material. For example, the connection member 1210 may include an organic circuit board including an organic material instead of the silicon circuit board. The connection member 1210 may be embedded in the second circuit board 1200.

For this purpose, the second circuit board 1200 may include a cavity, and the connection member 1210 may be disposed in the cavity of the second circuit board 1200. The connection member 1210 may horizontally connect a plurality of semiconductor devices disposed on the second circuit board 1200.

Referring to FIG. 1b, the semiconductor package according to the second embodiment may include a second circuit board 1200 and a semiconductor device 1300. In this case, the semiconductor package of the second embodiment may have a structure in which the first circuit board 1100 is removed compared to the semiconductor package of the first embodiment.

That is, the second circuit board 1200 of the second embodiment may function as a package circuit board while performing an interposer function.

The first connection part 1410 disposed on the lower surface of the second circuit board 1200 may couple the second circuit board 1200 to the main board of the electronic device.

Referring to FIG. 1c, the semiconductor package according to the third embodiment may include a first circuit board 1100 and a semiconductor device 1300.

In this case, the semiconductor package of the third embodiment may have a structure in which the second circuit board 1200 is omitted compared to the semiconductor package of the first embodiment.

That is, the first circuit board 1100 of the third embodiment can function as a package circuit board while also performing the function of connecting the semiconductor device 1300 and a main board. To this end, the first circuit board 1100 may include a connection member 1110 for connecting the plurality of semiconductor devices. The connection member 1110 may be an inorganic bridge or an organic material bridge connecting a plurality of semiconductor devices.

Referring to FIG. 1d, the semiconductor package of the fourth embodiment further may include a third semiconductor device 1330 compared to the semiconductor package of the third embodiment.

To this end, a fourth connection part 1440 may be disposed on the lower surface of the first circuit board 1100.

In addition, a third semiconductor device 1330 may be disposed on the fourth connection part 1400. That is, the semiconductor package of the fourth embodiment may have a structure in which semiconductor devices are mounted on upper and lower sides, respectively.

In this case, the third semiconductor device 1330 may have a structure disposed on the lower surface of the second circuit board 1200 in the semiconductor package of FIG. 1b.

Referring to FIG. 1e, the semiconductor package according to the fifth embodiment may include a first circuit board 1100. A first semiconductor device 1310 and a second semiconductor device 1320 may be disposed on the first circuit board 1100. To this end, a first connection part 1410 may be disposed between the first circuit board 1100 and the first semiconductor device 1310 the second semiconductor device 1320.

In addition, a connection member 1110 can be embedded in the first circuit board 1110. The connection member 1110 can horizontally connect the first and second semiconductor devices 1310 and 1320.

In addition, the first circuit board 1100 may include a conductive coupling portion 1450. The conductive coupling portion 1450 may further protrude from the first circuit board 1100 toward the second semiconductor device 1320. The conductive coupling portion 1450 may be referred to as a bump or, alternatively, may also be referred to as a post. The conductive coupling portion 1450 may be disposed to have a protruding structure on an electrode disposed on an uppermost side of the first circuit board 1100.

A third semiconductor device 1330 may be disposed on the conductive coupling portion 1450. In this case, the third semiconductor device 1330 may be connected to the first circuit board 1100 through the conductive coupling portion 1450. In addition, a second connection part 1420 may be disposed between the first semiconductor device 1310 and the second semiconductor device 1320 and the third semiconductor device 1330.

Accordingly, the third semiconductor device 1330 may be electrically connected to the first semiconductor device 1310 through the second connection part 1420.

That is, the third semiconductor device 1330 may be connected to the first circuit board 1100 through the conductive coupling portion 1450, and may be also connected to the first and second semiconductor devices 1310 and 1320 through the second connection part 1420.

In this case, the third semiconductor device 1330 may receive a power signal and/or electric power through the conductive coupling portion 1450. In addition, the third semiconductor device 1330 can exchange communication signals with the first and second semiconductor devices 1310 and 1320 through the second connection part 1420.

The semiconductor package according to the fifth embodiment may provide a power signal and/or electric power to the third semiconductor device 1330 through the conductive coupling portion 1450, thereby providing sufficient power for driving the third semiconductor device 1330 or enabling smooth control of a power operation.

Accordingly, the embodiment may improve the driving characteristics of the third semiconductor device 1330. That is, the embodiment may solve a problem of insufficient power provided to the third semiconductor device 1330. Furthermore, in the embodiment, at least one of a power signal, an electric power, and a communication signal of the third semiconductor device 1330 may be provided through different paths through the conductive coupling portion 1450 and the second connection part 1420. Through this, the embodiment can solve the problem that the communication signal is lost due to the power signal. For example, the embodiment may minimize mutual interference between communication signals of power signals.

Meanwhile, the second semiconductor device 1320 in the fifth embodiment may have a POP (Package On Package) structure in which a plurality of package circuit boards are stacked and may be disposed on the first circuit board 1100. For example, the third semiconductor device 1330 may be a memory package including a memory chip. In addition, the memory package may be coupled on the conductive coupling portion 1450. In this case, the memory package may not be connected to the first and second semiconductor devices 1310 and 1320.

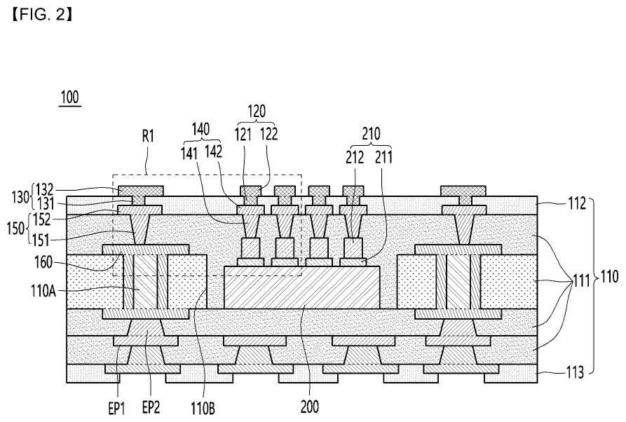

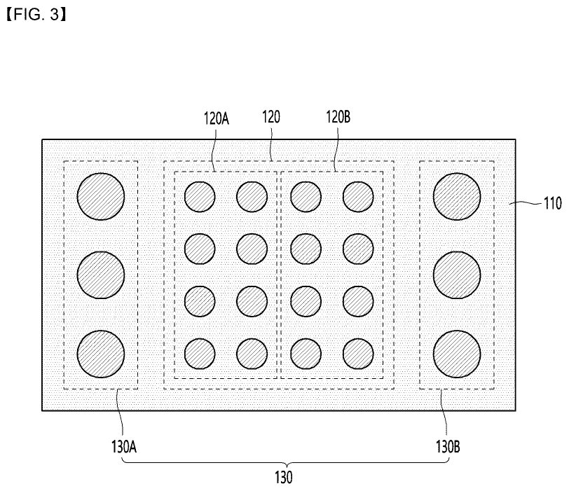

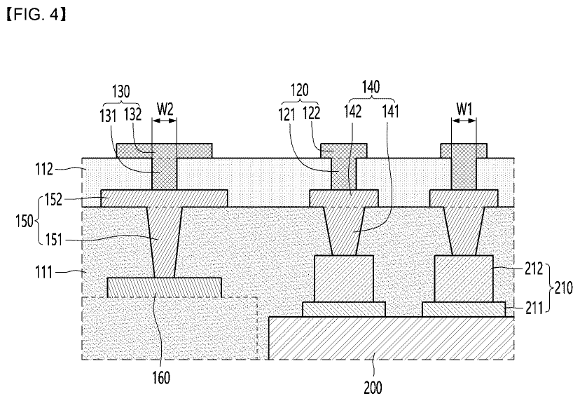

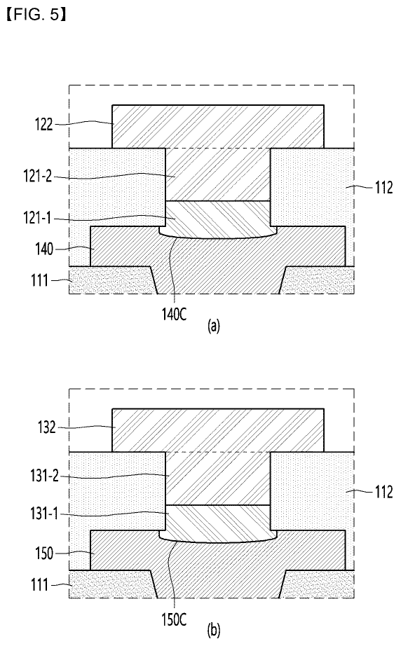

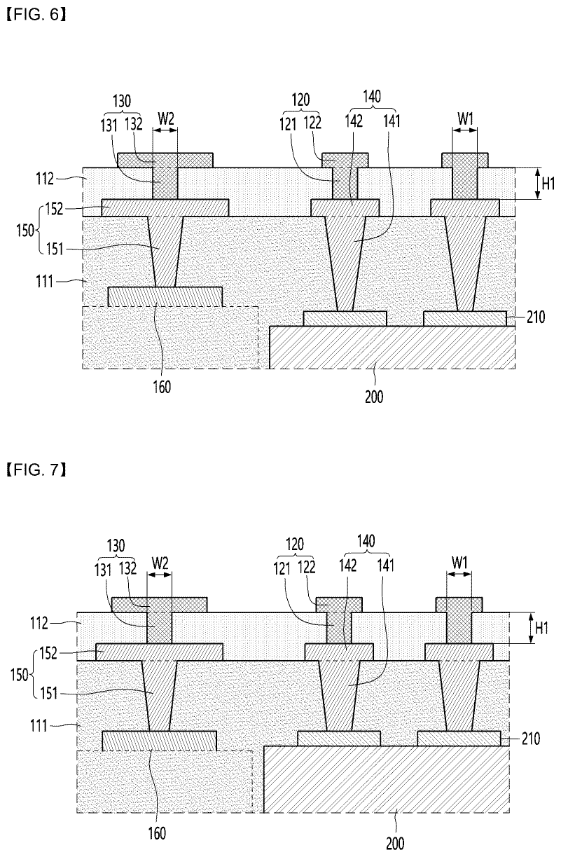

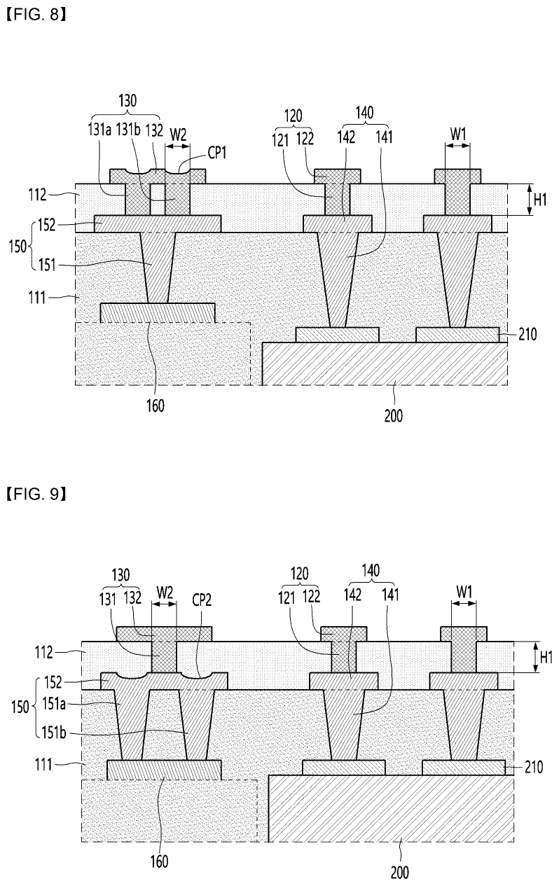

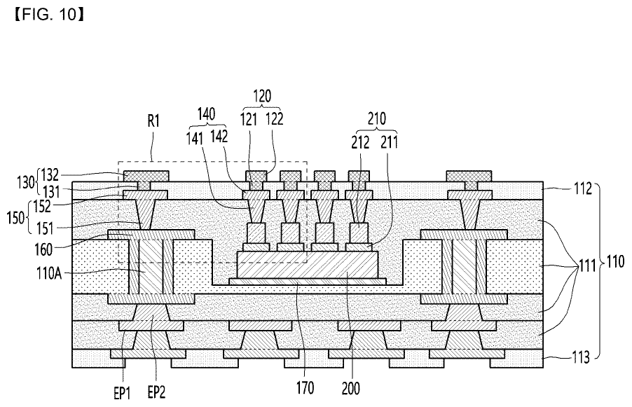

FIG. 2 is a cross-sectional view showing a circuit board according to a first embodiment, FIG. 3 is a plan view of the circuit board of FIG. 2 viewed from an upward direction, FIG. 4 is an enlarged cross-sectional view of a first region R1 of FIG. 2, FIG. 5 is a cross-sectional view showing a detailed layer structure of a first through electrode and a second through electrode of FIG. 2, FIG. 6 is an enlarged cross-sectional view of a first region of FIG. 2 according to a second embodiment, FIG. 7 is an enlarged cross-sectional view of a first region of FIG. 2 according to a third embodiment, FIG. 8 is an enlarged cross-sectional view of a first region of FIG. 2 according to a fourth embodiment, FIG. 9 is an enlarged cross-sectional view of a first region of FIG. 2 according to a fifth embodiment, and FIG. 10 is a cross-sectional view showing a circuit board according to a sixth embodiment.

Hereinafter, a circuit board and a connection member embedded in the circuit board provided in a semiconductor package according to an embodiment will be described with reference to FIGS. 2 to 10.

Referring to FIG. 2, the semiconductor package of the embodiment may include a circuit board 100 and a connection member 200 embedded in the circuit board 100. As described with reference to FIGS. 1a to 1e, the connection member 200 may horizontally connect a plurality of semiconductor devices, and may include high-density electrode patterns for this purpose. In addition, the connection member 200 may include at least one of an inorganic bridge and an organic bridge.

The circuit board 100 may provide a space in which the connection member 200 is embedded. In addition, the circuit board 100 may provide a space in which a plurality of semiconductor devices are mounted.

For example, first and second semiconductor devices may be mounted on the circuit board 100 while being spaced apart from each other in a horizontal direction. At least one first terminal provided in the first semiconductor device and at least one second terminal provided in the second semiconductor device may be electrically connected to each other through the connection member 200. For example, the first semiconductor device and the second semiconductor device may need to exchange signals with each other, and terminals for the mutual signal exchange may be electrically connected to the connection member 200.

The circuit board 100 for this purpose may include an insulating layer 110 and an electrode part.

The insulating layer 110 may include a plurality of layers. The insulating layer 110 may include a first insulating layer 111, a second insulating layer 112, and a third insulating layer 113. The first insulating layer 111 may constitute an inner layer of an insulating substrate. The second insulating layer 112 may be disposed on the first insulating layer 111. For example, the second insulating layer 112 may mean an insulating layer disposed at am uppermost side of the insulating substrate. The third insulating layer 113 may be disposed below the first insulating layer 111. For example, the third insulating layer 113 may mean an insulating layer disposed at a lowermost side of the insulating substrate.

The first insulating layer 111 of the circuit board may have a layer structure of at least one layer. Preferably, the first insulating layer 111 of the circuit board may have a plurality of laminated structures. The laminated structures may be distinguished by the electrode part. For example, the electrode part may include a first electrode EP1 and a second electrode EP2. The first electrode EP1 may mean a pad and/or a trace. The second electrode EP2 may mean a via electrode. The first electrode EP1 and the second electrode EP2 may have different widths and/or different vertical cross-sectional shapes. Accordingly, the laminated structure can be distinguished based on a difference in width and/or vertical cross-sectional shape of the first electrode EP1 and the second electrode EP2. Through the laminated structure described above, the circuit board of the embodiment can electrically and efficiently connect at least one semiconductor device and/or the second circuit board to the main board.

At this time, the first insulating layer 111 of the circuit board of FIG. 2 is illustrated as having a four-layer structure, but is not limited thereto. For example, the first insulating layer 111 of the circuit board may have a number of layers of three or less, or may have a number of layers of five or more.

In addition, when the first insulating layer 111 includes a plurality of layers, each of the plurality of layers may include a same insulating material. In this case, an interface between the plurality of layers of the first insulating layer 111 may not be distinguished, and thus, the laminated structure may be distinguished based on the first electrode EP1 and the second electrode EP2.

In addition, when the first insulating layer 111 includes a plurality of layers, at least one layer among the plurality of layers may include an insulating material different from at least one other layer. In this case, an interface between the plurality of layers including the different insulating materials may be distinguished.

Meanwhile, at least one layer among the plurality of layers of the first insulating layer 111 may include a reinforcing member. In one embodiment, the reinforcing member may mean glass fiber. In another embodiment, the reinforcing member may mean GCP (Glass Core Primer). In addition, the plurality of layers of the first insulating layer 111 in another embodiment may not include a reinforcing member such as glass fiber and/or GCP.

Meanwhile, a connection member 200 may be embedded in the first insulating layer 111. For example, the first insulating layer 111 may include a receiving portion 110B in a form of a through hole in which the connection member 200 is received. The connection member 200 may be embedded in the receiving portion 110B of the first insulating layer 111. Here, being embedded may mean that the connection member 200 is entirely covered with the first insulating layer 111.

The insulating layer 110 of the circuit board may include a second insulating layer 112 and a third insulating layer 113. The second insulating layer 112 and the third insulating layer 113 of the circuit board may be resist layers. For example, the second insulating layer 112 of the circuit board may be a first resist layer disposed at an uppermost side of the circuit board. In addition, the third insulating layer 113 of the circuit board may be a second resist layer disposed at a lowermost side of the circuit board.

At this time, the second insulating layer 112 of the circuit board may include a same insulating material as the first insulating layer 111 of the circuit board. For example, when the first insulating layer 111 of the circuit board is composed of a plurality of layers, a first insulating layer most adjacent to the second insulating layer 112 among the first insulating layers of the plurality of layers may include a same insulating material as the second insulating layer 112. In this case, an interface between the first insulating layer 111 and the second insulating layer 112 of the circuit board may not be distinguished. Correspondingly, the third insulating layer 113 of the circuit board may include a same insulating material as the first insulating layer 111 of the circuit board.

The second insulating layer 112 and the third insulating layer 113 of the circuit board may have a function of protecting upper and lower surfaces of the first insulating layer 111 of the circuit board, respectively. Accordingly, the second insulating layer 112 and the third insulating layer 113 of the circuit board may be referred to as protective layers. The second insulating layer 112 and the third insulating layer 113 of the circuit board may be solder resist layers containing an organic polymer material. For example, the second insulating layer 112 and the third insulating layer 113 of the circuit board may contain an epoxy acrylate series resin. In detail, the second insulating layer 112 and the third insulating layer 113 of the circuit board may contain a resin, a curing agent, a photo initiator, a pigment, a solvent, a filler, an additive, an acrylic series monomer, etc. However, the embodiment is not limited thereto, and the second insulating layer 112 and the third insulating layer 113 of the circuit board may be any one of a photo solder resist layer, a cover-lay, and a polymer material.

The circuit board 100 may include an electrode part.

The electrode part may penetrate at least a portion of the insulating layer 110.

The electrode part may include a plurality of electrode parts depending on a location and a function.

The electrode part may include a first electrode part 120. The first electrode part 120 may penetrate from an upper surface of the insulating layer 110 to a partial region of the insulating layer. The first electrode part 120 may vertically overlap the connection member 200. The first electrode part 120 may mean an electrode electrically connected to the connection member 200.

The first electrode part 120 may protrude on the insulating layer 110 while penetrating at least a portion of the insulating layer 110.

For example, the first electrode part 120 may include a first through part 121 penetrating from the upper surface of the second insulating layer 112 to a partial region of the insulating layer. The first through part 121 may be a through electrode penetrating at least a part of the second insulating layer 112. The first through part 121 may vertically overlap the connection member 200. Preferably, the connection member 200 may include a first connection electrode 210. The first connection electrode 210 may be a pad provided at an outermost layer of the connection member 200.

The first electrode part 120 may include a first protruding part 122 provided on the first through part 121 and protruding on the second insulating layer 112.

At this time, the first through part 121 and the first protruding part 122 of the first electrode part 120 may be formed integrally with each other as one electrode, and may be divided into a part penetrating the second insulating layer 112 and a part protruding on the second insulating layer 112.

Meanwhile, the electrode part of the circuit board 100 may include a second electrode part 130. The second electrode part 130 may penetrate from an upper surface of the insulating layer 110 to a partial region of the insulating layer. The second electrode part 130 may overlap horizontally with the first electrode part 120. For example, the second electrode part 130 may be an electrode disposed on a same layer as the first electrode part 120.

The second electrode part 130 may not overlap vertically with the connection member 200. That is, the second electrode part 130 may not be directly connected to the connection member 200. The second electrode part 130 may mean an electrode that overlaps horizontally with the first electrode part 120 and does not overlap vertically with the connection member 200.

The second electrode part 130 may protrude on the insulating layer 110 while penetrating from the upper surface of the insulating layer 110 to a partial region of the insulating layer.

For example, the second electrode part 130 may include a second through part 131 penetrating from the upper surface of the second insulating layer 112 to a partial region of the insulating layer. The second through part 131 may be a through electrode penetrating at least a portion of the second insulating layer 112. The second through part 131 may vertically overlap with the connection member 200. The second through part 131 may not vertically overlap with the first connection electrode 210 of the connection member 200.

The second electrode part 130 may include a second protruding part 132 provided on the second through part 131 and protruding on the second insulating layer 112.

At this time, the second through part 131 and the second protruding part 132 of the second electrode part 130 may be formed as one electrode integrally with each other, and may be divided into a part penetrating the second insulating layer 112 and a part protruding on the second insulating layer 112.

The first electrode part 120 and the second electrode part 130 may be post bumps connected to a semiconductor device.

That is, as a width of the terminals of the semiconductor device coupled on the circuit board and a pitch of the terminals are miniaturized, when the semiconductor device is mounted using a conductive adhesive such as solder, the conductive adhesive may spread, which may cause a problem in which a plurality of conductive adhesives are connected to each other. Accordingly, the embodiment may perform thermal compression bonding to reduce a volume of the conductive adhesive. At this time, if the circuit board 100 does not include the first electrode part 120 and the second electrode part 130 having a structure protruding above the insulating layer 110, it may be difficult to reduce a volume of the conductive adhesive. This may be because a height of the electrode on which the conductive adhesive is disposed is positioned lower than a height of the insulating layer 110, and thus a volume of the conductive adhesive increases by a difference in the height of the electrode and the height of the insulating layer.

Therefore, the circuit board 100 of the embodiment may have a first electrode part 120 and a second electrode part 130 having a protruding structure to secure alignment with the terminal of the semiconductor device and diffusion prevention power to prevent the intermetallic compound (IMC) formed between the conductive adhesive and the electrode part from diffusing into the circuit board.

Referring to FIG. 3, each of the first electrode part 120 and the second electrode part 130 may be divided into a plurality of groups.

The first electrode part 120 may include a first electrode part 120A of a first group and a first electrode part 120B of a second group. The first electrode part 120A of the first group may mean an electrode part overlapping the first semiconductor device in a vertical direction. For example, the first electrode part 120A of the first group may mean an electrode part connected to the first semiconductor device. The first electrode part 120B of the second group may mean an electrode part overlapping the second semiconductor device in a vertical direction. For example, the first electrode part 120B of the second group may mean an electrode part connected to the second semiconductor device.

The second electrode part 130 may include the second electrode part 130A of the first group and the second electrode part 130B of the second group. The second electrode part 130A of the first group may be disposed adjacent to the first electrode part 120A of the first group. For example, the second electrode part 130A of the first group may be disposed at one side of the first electrode part 120A of the first group. The second electrode part 130A of the first group may overlap the first semiconductor device in a vertical direction. The second electrode part 130A of the first group may be connected to the first semiconductor device. The second electrode part 130B of the second group may be disposed adjacent to the first electrode part 120B of the second group. For example, the second electrode part 130B of the second group may be disposed at the other side of the first electrode part 120B of the second group. The second electrode part 130B of the second group may overlap the second semiconductor device in a vertical direction. The second electrode part 130B of the second group may be connected to the first semiconductor device.

Meanwhile, a height of an upper surface of the first electrode part 120 may be same as a height of an upper surface of the second electrode part 130. For example, the upper surface of the first through part 121 of the first electrode part 120 may be positioned on a same plane as the upper surface of the second through part 131 of the second electrode part 130. In addition, the upper surface of the first protruding part 122 of the first electrode part 120 may be positioned on a same plane as the upper surface of the second protruding part 132 of the second electrode part 130.

To this end, a size of the first through part 121 of the first electrode part 120 may be same as a size of the second through part 131 of the second electrode part 130. Here, the same size may mean that a deviation between a size of the first through part 121 of the first electrode part 120 and a size of the second through part 131 of the second electrode part 130 is 20% or less, 15% or less, 10% or less, or 5% or less.

For example, the size of the first through part 121 of the first electrode part 120 may satisfy a range of 80% to 100% of the size of the second through part 131 of the second electrode part 130. If the deviation between the size of the first through part 121 of the first electrode part 120 and the size of the second through part 131 of the second electrode part 130 exceeds 20%, or if the size of one of the first through part 121 of the first electrode part 120 and the second through part 131 of the second electrode part 130 is less than 80% or exceeds 100% of the size of another one of the first through part 121 of the first electrode part 120 and the second through part 131 of the second electrode part 130, the semiconductor device may not be stably mounted on the first electrode part 120 and the second electrode part 130.

Specifically, when the sizes of the first through part 121 and the second through part 131 are out of the above range, a plating deviation may occur in a process of plating the first through part 121 and the second through part 131. Each of the first through part 121 and the second through part 131 may be formed by filling an inside of each of a first through hole and a second through hole penetrating at least a portion of the second insulating layer 112 with a conductive material. In addition, when a difference in sizes of the first through hole and the second through hole is out of the above range, a difference may occur between a plating amount in the first through hole and a plating amount in the second through hole. Due to this, a deviation may occur between the height of the upper surface of the first protruding part 122 disposed on the first through part 121 and the height of the upper surface of the second protruding part 132 disposed on the second through part 131. For example, a protruding part of an electrode part having a relatively large size may have a lower height than a protruding part of an electrode part having a relatively small size.

If the upper surfaces of the first electrode part 120 and the second electrode part 130 are not flat and have a height difference, a problem may occur in which the semiconductor device is coupled in a tilted state on the first electrode part 120 and the second electrode part 130. In addition, if there is a height difference as described above, a protruding part positioned relatively high may be electrically connected to the semiconductor device, but a protruding part positioned relatively low may not be electrically connected to the semiconductor device. Conversely, a protruding part positioned relatively low may be electrically connected to the semiconductor device, but a protruding part positioned relatively high may not be electrically connected to the semiconductor device. As a result, the semiconductor device may not operate smoothly, and further, the electronic product or server may not operate smoothly.

In addition, the circuit board can perform impedance matching by adjusting a width or a thickness of the electrode parts. At this time, if a difference in the thickness of the first electrode part 120 and the second electrode part 130 occurs due to a plating deviation according to a size difference between the first through part 121 and the second through part 131, the impedance matching may not be performed normally, and an electrical reliability problem of the semiconductor package may occur due to the impedance mismatching.

Therefore, the embodiment allows the difference between the size of the first through part 121 of the first electrode part 120 and the size of the second through part 131 of the second electrode part 130 to satisfy the above range, thereby minimizing the height difference between the first protruding part 122 of the first electrode part 120 and the second protruding part 132 of the second electrode part 130, and further allowing the first protruding part 122 and the second protruding part 132 to have substantially a same height.

Meanwhile, a size of the first through part 121 may mean a density and/or a volume of the first through part 121. In addition, the size of the second through part 131 may mean a density and/or a volume of the second through part 131. For example, when a thickness of the first through part 121 in the vertical direction is the same as a thickness of the second through part 131 in the vertical direction, a width of the first through part 121 may have a range of 80% to 100% of a width of the second through part 131. For example, when a thickness of the first through part 121 in the vertical direction is smaller than a thickness of the second through part 131 in the vertical direction, a width of the first through part 121 may be larger than a width of the second through part 131 by the thickness difference. For example, when a thickness of the first through part 121 in the vertical direction is larger than a thickness of the second through part 131 in the vertical direction, a width of the first through part 121 may be smaller than the width of a second through part 131 by the thickness difference.

In one embodiment, a thickness of the first through part 121 in the vertical direction may be the same as a thickness of the second through part 131 in the vertical direction. A width W2 of the second through part 131 in the horizontal direction may be in a range of 80% to 100% of a width W1 of the first through part 121 in the horizontal direction. Through this, the embodiment can eliminate a plating deviation between the first through part 121 and the second through part 131, and through this, the first protruding part 122 of the first electrode part 120 and the second protruding part 132 of the second electrode part 130 can have uniform heights.

Meanwhile, a width W1 of the first through part 121 may be determined by a width of the first connection electrode 210 provided in the connection member 200. Therefore, it may be difficult to change the width W1 of the first through part 121. Therefore, the width W1 of the first through part 121 may be determined based on the width of the first connection electrode 210 of the connection member 200, and the width W2 of the second through part 131 may be adjusted to correspond to the width W1 of the first through part 121.

For example, the width W1 of the first through part 121 may satisfy a range of 10 μm to 40 μm. Preferably, the width W1 of the first through part 121 may satisfy a range of 12 μm to 35 μm. More preferably, the width W1 of the first through part 121 may satisfy a range of 15 μm to 30 μm. If the width W1 of the first through part 121 is smaller than 10 μm, an allowable current of a signal transmitted through the first through part 121 may decrease. In addition, if the width W1 of the first through part 121 is smaller than 10 μm, a resistance of the first through part 121 may increase. In addition, if the width W1 of the first through part 121 is larger than 40 μm, it may be difficult to arrange all of the plurality of first through parts 121 that vertically overlap with the connection member 200.

Meanwhile, the range of the width W1 of the first through part 121 is determined based on the width of the first connection electrode 210 of the connection member 200, and the width W2 of the second through part 131 may be determined to be the same as or have a deviation of 20% or less.

At this time, the width of the first through part 121 and the width of the second through part 131 may correspond to widths of the first and second through holes penetrating the corresponding second insulating layer 112. At this time, the first and second through holes may be formed through an exposure and development process. In another embodiment, the first and second through holes may be formed through a laser process.

Specifically, when the first and second through holes are formed through the exposure and development process, widths of the first and second through holes may be determined by an exposure resolution in the exposure process. However, a minimum width of the first and second through holes that can be formed in a general exposure process capability is about 50 μm. At this time, the width of the first and second through holes of the embodiment is 40 μm or less, and accordingly, the embodiment can form the first and second through holes for forming the first through part 121 and the second through part 131 through a laser process.

Accordingly, the first and second through holes can have a shape whose width changes in a thickness direction. Correspondingly, the first through part 121 of the first electrode part 120 and the second through part 131 of the second electrode part 130 can have a shape whose width changes in the thickness direction.

Specifically, the first through part 121 and the second through part 131 can have a slope in which the width gradually decreases from an upper surface to a lower surface. At this time, the width W1 of the first through part 121 and the width W2 of the second through part 131 may mean a width of a region having a largest width in an entire region in the thickness direction.

Accordingly, a width of a lower surface of each of the first through part 121 and the second through part 131 may have a width smaller than the width of an upper surface of each of the first through part 121 and the second through part 131.

Meanwhile, referring to FIG. 4, the electrode part may further include a third electrode part 140 disposed between the connection member 200 and the first electrode part 120. The third electrode part 140 may electrically connect the first connection electrode 210 of the connection member 200 and the first electrode part 120.

In addition, the electrode part may include a fourth electrode part 150 that overlaps the third electrode part 140 in a horizontal direction and does not overlap the connection member 200 in a vertical direction. The fourth electrode part 150 may be positioned below the second electrode part 130 to connect the fourth electrode part 150 and internal electrodes of the circuit board 100.

At this time, since the first through part 121 and the second through part 131 have a difference in width in the thickness direction as described above, a bonding force between the first through part 121 and the third electrode part 140 and/or a bonding force between the second through part 131 and the fourth electrode part 150 may be reduced. That is, as a contact area between the first through part 121 and the third electrode part 140 decreases, cracks may occur in a lower region of the first through part 121 in contact with the third electrode part 140 due to various factors (e.g., thermal stress). In addition, as the contact area between the second through part 131 and the fourth electrode part 150 decreases, cracks may occur in a lower region of the second through part 131 in contact with the fourth electrode part 150 due to various factors (e.g., thermal stress).

Therefore, as shown in FIG. 5, each of the first through part 121 of the first electrode part 120 and the second through part 131 of the second electrode part 130 may include a plurality of metal layers.

For example, referring to (a) of FIG. 5, the first through part 121 may include a first metal layer 121-1 disposed on the third electrode part 140. In addition, the first through part 121 may include a second metal layer 121-2 disposed on the first metal layer 121-1. In this case, the first metal layer 121-1 and the second metal layer 121-2 may include different metal materials.

Preferably, the first metal layer 121-1 may include nickel. In addition, the second metal layer 121-2 may include copper. The first metal layer 121-1 may improve the bonding strength between the second metal layer 121-2 and the third electrode part 140. For example, when the second metal layer 121-2 is directly disposed on the third electrode part 140, oxidation of the third electrode part 140 may occur, and as a result, the bonding strength between the third electrode part 140 and the second metal layer 121-2 may be reduced. Therefore, the first metal layer 121-1 may function to prevent oxidation of the third electrode part 140 while improving the bonding strength between the second metal layer 121-2 and the third electrode part 140. In addition, the first metal layer 121-1 can solve a problem of the first through part 121 being peeled off from the third electrode part 140 due to contraction and expansion of the second insulating layer 112 caused by thermal stress.

Specifically, when the first metal layer 121-1 includes nickel, the adhesion between the third electrode part 140 and the first through part 121 of the first electrode part 120 can be improved. In addition, when electrically connecting with the first electrode part 120 through a material such as solder is formed later, the solder may diffuse to form an inter-metallic compound, and the inter-metallic compound has a problem of poor mechanical and electrical reliability. In particular, if the second metal layer 121-2 is made of copper, the problem of forming the inter-metallic compound may be further aggravated. However, if nickel is disposed, the diffusion of solder can be prevented, thereby preventing the formation of the inter-metallic compound, thereby improving the electrical and mechanical reliability of the semiconductor package.

At this time, the third electrode part 140 may include a crevice 140C. For example, an upper surface of the third electrode part 140 may include a crevice 140C vertically overlapping the first through part 121 and concave toward the lower surface of the third electrode part 140. The crevice 140C may be filled with the first metal layer 121-1 of the first through part 121. Through this, the contact area between the third electrode part 140 and the first through part 121 can be increased, and thus the bonding strength can be further improved.

In addition, referring to (b) of FIG. 5, the second through part 131 of the second electrode part 130 may also include a first metal layer 133-1 and a second metal layer 133-2. The first metal layer 133-1 of the second through part 131 may be disposed on the fourth electrode part 150. In addition, the second metal layer 133-2 of the second electrode part 130 may be disposed on the first metal layer 133-1. A crevice 150C may be provided at an upper surface of the fourth electrode part 150, and the first metal layer 133-1 of the second through part 131 may be provided to fill the crevice 150C of the fourth electrode part 150.

Meanwhile, the third electrode part 140 connected to the first electrode part 120 may include a first extension part 141 and a first pad part 142. The first extension part 141 of the third electrode part 140 may be connected to the first connection electrode 210 of the connection member 200. The first pad part 142 of the third electrode part 140 may be disposed between the first extension part 141 and the first through part 121 of the first electrode part 120, and may connect them.

Meanwhile, the fourth electrode part 150 connected to the second electrode part 130 may include a second extension part 151 and a second pad part 152. The second extension part 151 of the fourth electrode part 150 may be connected to the second connection electrode 160 provided on the circuit board. The second connection electrode 160 may be horizontally overlapped with the first connection electrode 210 and/or the connection member 200. The second pad part 152 of the fourth electrode part 150 may be disposed between the second extension part 151 and the second through part 131 of the second electrode part 130, and may connect them.

The first connection electrode 210 of the connection member 200 may include a plurality of electrode parts. For example, the first connection electrode 210 may include a first electrode part 211 disposed on the connection member 200. The first electrode part 211 may refer to an electrode part positioned at an uppermost side among a plurality of electrode parts provided on the connection member 200.

In addition, the first connection electrode 210 of the connection member 200 may include a second electrode part 212 positioned on the first electrode part 211. The second electrode part 212 may protrude to have a certain height on the first electrode part 211. The second electrode part 212 may be referred to as a post. The second electrode part 212 may be provided on the connection member 200 to improve alignment between the first electrode part 211 and the third electrode part 140. For example, the second electrode part 212 may be disposed on the first electrode part 211 at a certain height, thereby allowing the first electrode part 211 and the plurality of first through parts 121 to be aligned in the vertical direction.

At this time, the first connection electrode 210 and the second connection electrode 160 of the connection member 200 may have different heights.

For example, there may be a difference in a depth of the receiving portion 110B provided in the insulating layer 110 and a thickness of the connection member 200, and the first connection electrode 210 of the connection member 200 may be positioned higher or lower than the second connection electrode 160 in response to the difference in thickness.

Accordingly, a difference may occur between a height of an upper surface of the third electrode part 140 and a height of an upper surface of the fourth electrode part 150.

For example, as illustrated in FIG. 4, the upper surface of the first connection electrode 210 of the connection member 200 may be positioned higher than the upper surface of the second connection electrode 160. In this case, the upper surface of the third electrode part 140 may be positioned higher than the upper surface of the fourth electrode part 150. In this case, when the width of the first through part 121 of the first electrode part 120 and the width of the second through part 131 of the second electrode part 130 are same, an upper surface of the first electrode part 120 may be positioned higher than an upper surface of the second electrode part 130. Accordingly, the embodiment allows the width W2 of the second through part 131 to be smaller than the width W1 of the first through part 121. For example, the width W1 of the first through part 121 is made larger than the width W2 of the second through part 131 by the difference in height between the upper surface of the third electrode part 140 and the upper surface of the fourth electrode part 150. Through this, the embodiment can make the thickness of the first through part 121 smaller than the thickness of the second through part 131 by making the difference in the width, and through this, the height of the upper surface of the first protruding part 122 of the first electrode part 120 can be made equal to the height of the upper surface of the second protruding part 132 of the second electrode part 130.

Meanwhile, as illustrated in FIG. 6, the upper surface of the first connection electrode 210 of the connection member 200 can be positioned lower than the upper surface of the second connection electrode 160. For example, the first connecting electrode 210 may include only the first electrode part.

In this case, the upper surface of the third electrode part 140 may be positioned lower than the upper surface of the fourth electrode part 150. In this case, when the width of the first through part 121 of the first electrode part 120 and the width of the second through part 131 of the second electrode part 130 are same, the upper surface of the first electrode part 120 may be positioned lower than the upper surface of the second electrode part 130. Accordingly, the embodiment allows the width W2 of the second through part 131 to be larger than the width W1 of the first through part 121. For example, the width W1 of the first through part 121 is made smaller than the width W2 of the second through part 131 by the difference in height between the upper surface of the third electrode part 140 and the upper surface of the fourth electrode part 150. Through this, the embodiment can make the thickness of the first through part 121 larger than the thickness of the second through part 131 by making the difference in the width, and through this, the height of the upper surface of the first protruding part 122 of the first electrode part 120 can be made the same as the height of the upper surface of the second protruding part 132 of the second electrode part 130.

Meanwhile, as illustrated in FIG. 7, the upper surface of the first connection electrode 210 of the connection member 200 can be positioned on a same plane as the upper surface of the second connection electrode 160. And, sizes of the third electrode part 140 and the fourth electrode part 150 may be the same, and accordingly, the height of the upper surface of the third electrode part 140 and the height of the upper surface of the fourth electrode part 150 may be the same. In this case, the thickness of the first through part 121 and the thickness of the second through part 131 may be the same, and further, the width of the first through part 121 and the width of the second through part 131 may be the same.

Meanwhile, as illustrated in FIG. 8, the second electrode part 130 may include at least a plurality of sub-through parts.

Specifically, the first electrode part 120 described above may be provided in multiple units while being spaced apart from each other, and the second electrode part 130 may also be provided in multiple units while being spaced apart from each other. In addition, the size of the first through part of each of the plurality of first electrode parts may correspond to the size of the second through part of each of the plurality of second electrode parts.

Meanwhile, at least one of the plurality of second electrode parts 130 may include a plurality of sub-electrodes commonly connected to one second protruding part 132.

Specifically, the second electrode part 130 may include second electrode parts 130A of a first group connected to the first semiconductor device and second electrode parts 130B of a second group connected to the second semiconductor device. In addition, at least one of the second electrode parts of the first group and the second electrode parts of the second group may include a plurality of sub-through parts vertically overlapping one second protruding part 132.

Specifically, the second through part 131 may be reduced in size compared to a size of a conventional through part in order to have the same size as the first through part 121. In addition, when the size of the second through part 131 decreases, the allowable current of the signal may decrease accordingly. In addition, when the size of the second through part 131 decreases, the contact area between the second through part 131 and the insulating layer 110 decreases, and accordingly, the adhesion between the second through part 131 and the insulating layer 110 may decrease. In addition, when the width of the second through part 131 decreases, the heat transfer characteristics of the heat transferred through the second through part 131 may decrease, and thus, the heat dissipation characteristics may decrease. In addition, when the size of the second through part 131 decreases, a problem may occur in which an impedance matching state is misaligned accordingly, and thus, a design of other electrode parts provided in the circuit board may need to be changed to perform impedance matching.

Therefore, the embodiment allows the second through part 131 to have multiple sub-through parts, thereby improving the heat transfer characteristics, increasing the heat dissipation effect, and maintaining the impedance matching state accordingly.

For example, at least one of the plurality of second electrode parts 130 may include a second protruding part 132 and a first sub-through part 131a and a second sub-through parts 131b vertically overlapping the second protruding part 132 and horizontally spaced from each other.

The first sub-through part 131a and the second sub-through part 131b may be commonly connected to one second protruding part 132. For example, the first sub-through part 131a and the second sub-through part 131b may each be vertically overlapped with one second protruding part 132.

In addition, the first sub-through part 131a and the second sub-through part 131b may have a same thickness and a same width. For example, the first sub-through part 131a and the second sub-through part 131b may have a same volume. Preferably, the first sub-through part 131a and the second sub-through part 131b may have a same size.

In addition, the first sub-through part 131a may have a same size as the first through part 121. In addition, the second sub-through part 131b may have a same volume as the first through part 121. In addition, the first sub-through part 131a may have a same size as the first through part 121. Through this, the embodiment can ensure that the first electrode part 120 and the second electrode part 130 have uniform heights even if the second through part 131 of the second electrode part 130 includes the first sub-through part 131a and the second sub-through part 131b.

However, an upper surface of the second protruding part 132 may have a step. For example, the second protruding part 132 may have a step as it vertically overlaps with a plurality of sub-through parts. For example, the second protruding part 132 may include a dimple region provided in a region vertically overlapping with a plurality of through parts. For example, the second protruding part 132 may have a concave portion CP provided in each of a region vertically overlapping with the first sub-through part 131a and a region vertically overlapping with the second sub-through part 131b.

The concave portion CP may allow a conductive adhesive material such as solder to be stably settled on the second protruding part 134. For example, the concave portion CP may function as a dam to prevent movement of the solder as the solder is settled.

Meanwhile, as illustrated in FIG. 9, in order to improve the heat dissipation characteristics and/or impedance matching, the fourth electrode part 150, not the second electrode part 130, may include a plurality of sub-extension parts.

For example, at least one of the plurality of fourth electrode parts 150 may include a first sub-extension part 141a and a second sub-extension part 141b that are vertically overlapped with one second pad part 152 and horizontally spaced from each other. In addition, the first sub-extension part 141a and the second sub-extension part 141b of the fourth electrode part 150 may improve the heat dissipation characteristics while improving the accuracy of the impedance matching state that changes in response to the decrease in the width of the second through part 131.

In addition, an upper surface of the second pad part 152 may include a concave portion CP2 vertically overlapping the first sub-extension part 141a and the second sub-extension part 141b. In addition, the concave portion CP2 may have a function of increasing a contact area with the second insulating layer 112, thereby preventing the second insulating layer 112 from being peeled off.

In addition, the concave portion CP2 may function as a clevis 150C of the fourth electrode part 150 described with reference to FIG. 5, thereby omitting a separate process for forming the clevis 150C.

Meanwhile, referring to FIG. 10, the connection member 200 may be disposed in a receiving portion provided in the first insulating layer 110. At this time, the receiving portion may be provided in at least a part of a plurality of layers of the first insulating layer 110. The receiving portion may be a recessed shape rather than a through-hole shape. Accordingly, an adhesive member 170 may be provided on the recess.

The adhesive member 170 may enable the connection member 200 to be firmly fixed to the insulating layer 110. The adhesive member 170 may have a different width from the connection member 200. In addition, the adhesive member 170 may be larger than the width of the connection member 200. Through this, the connection member 200 may be prevented from being peeled off due to various damages applied in an operating environment of the semiconductor package.

The embodiment can minimize a height deviation of first and second electrode parts penetrating from an upper surface of the insulating layer to a partial region of the insulating layer while being connected to the semiconductor device.

Specifically, the first electrode part can be vertically overlapped with the connection member, and the second electrode part can be horizontally overlapped with the first electrode part without being vertically overlapped with the connection member. The first electrode part can include a first through part penetrating at least a part of the insulating layer and a first protruding part positioned on the first through part and protruding on the insulating layer. The second electrode part can include a second through part penetrating at least a part of the insulating layer and a second protruding part positioned on the second through part and protruding on the insulating layer. At this time, a size of the second through part can correspond to a size of the first through part. Preferably, a size of the second through part can satisfy a range of 80% to 100% of a size of the first through part. The embodiment can minimize a height deviation between the first electrode part and the second electrode part caused by a size difference between the first through part and the second through part, thereby allowing the semiconductor device to be stably disposed on the first and second electrode parts.

Preferably, a thickness of the first through part in a vertical direction can be same as a thickness of the second through part in the vertical direction, and a width of the first through part in a horizontal direction can be the same as a width of the second through part in the horizontal direction.

In addition, a thickness of the first through part in the vertical direction can be smaller than a thickness of the second through part in the vertical direction, and a width of the first through part in the horizontal direction can be larger than a width of the second through part in the horizontal direction.

In addition, a thickness of the first through part in the vertical direction can be larger than a thickness of the second through part in the vertical direction, and a width of the first through part in the horizontal direction can be smaller than a width of the second through part in the horizontal direction.

Accordingly, the embodiment can allow a height of the first electrode part and a height of the second electrode part to be uniform. The first and second semiconductor devices can be stably disposed. Therefore, the embodiment can improve operating characteristics of the first and second semiconductor devices. Furthermore, the embodiment can allow the first and second semiconductor devices to operate smoothly, and through this, the electronic product or server can operate smoothly.

In addition, the embodiment can prevent a change in impedance that occurs due to a change in the thickness of the first electrode part and the second electrode part by making the first electrode part and the second electrode part have a same height, thereby further improving the electrical reliability.

Meanwhile, the second through part of the second electrode part can include a plurality of sub-through parts that overlap each other vertically with one second pad part. In addition, a size of each of the plurality of sub-through parts can correspond to a size of the first through part. Accordingly, even if the second through part includes a plurality of sub-through parts, the first electrode part and the second electrode part can have a uniform height. In addition, a concave portion can be provided at an upper surface of the second protruding part that vertically overlaps the plurality of sub-through parts. In addition, a conductive adhesive material such as solder can be stably settled on the concave portion provided in the second protruding part. For example, the concave portion of the second protruding part can serve as a dam function that prevents movement of a solder while guiding a settlement position where the solder is settled. Furthermore, the embodiment can improve heat dissipation characteristics of the semiconductor package by allowing heat to be transferred through the plurality of sub-through parts, and can further improve the operating characteristics of the semiconductor package.

Furthermore, the embodiment can prevent a change in impedance caused by a decrease in the width of the second through part since the second through part includes a plurality of sub-through parts, and thereby improve operating characteristics of the first and second semiconductor devices. Furthermore, the embodiment can enable smooth operation of the first and second semiconductor devices, thereby enabling smooth operation of electronic products or servers.

On the other hand, when the circuit board having the above-described characteristics of the invention is used in an IT device or home appliance such as a smart phone, a server computer, a TV, and the like, functions such as signal transmission or power supply can be stably performed. For example, when a circuit board having the features of the present invention performs a semiconductor package function, the circuit board can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1.-10. (canceled)

11. A circuit board comprising:
a build-up insulating layer including a plurality of insulating layers laminated along a vertical direction;
a plurality of electrode parts including a through part penetrating from an upper surface of the build-up insulating layer to a partial region of the build-up insulating layer; and
a connection member embedded in the build-up insulating layer,
wherein the plurality of electrode parts include:
a first electrode part including a first through part overlapping the connection member in a vertical direction, and
a second electrode part including a second through part that does not overlap the connection member in the vertical direction, and
wherein a size of the first through part satisfies a range of 80% to 100% of a size of the second through part.

12. The circuit board of claim 11, wherein each of the first and second through parts is provided in a plurality of numbers, and
wherein a size of each of a plurality of first through parts satisfies a range of 80% to 100% of a size of each of a plurality of second through parts.

13. The circuit board of claim 12, wherein the plurality of first through parts overlap the plurality of second through parts in a horizontal direction.

14. The circuit board of claim 11, wherein thicknesses of the first through part and the second through part in the vertical direction are same, and
wherein widths of the first through part and the second through part in a horizontal direction are same.

15. The circuit board of claim 11, wherein a thickness of the first through part in the vertical direction is smaller than a thickness of the second through part in the vertical direction, and
wherein a width of the first through part in a horizontal direction is greater than a width of the second through part in the horizontal direction.

16. The circuit board of claim 11, wherein a thickness of the first through part in the vertical direction is greater than a thickness of the second through part in the vertical direction, and
wherein a width of the first through part in a horizontal direction is smaller than a width of the second through part in the horizontal direction.

17. The circuit board of claim 13, wherein at least one of a density and a volume of the first through part satisfies a range of 80% to 100% of at least one of a density and a volume of the second through part.

18. The circuit board of claim 11, wherein the first electrode part includes a first protruding part disposed on the first through part and protruding on the build-up insulating layer, and
wherein the second electrode part includes a second protruding part disposed on the second through part and protruding on the build-up insulating layer.

19. The circuit board of claim 18, wherein a height of an upper surface of the first protruding part is same as a height of an upper surface of the second protruding part.

20. The circuit board of claim 11, wherein a width of the first through part in a horizontal direction satisfies a range of 10 μm to 40 μm.

21. The circuit board of claim 11, wherein each of the first and second through parts has a slope whose width gradually decreases from an upper surface toward a lower surface.

22. The circuit board of claim 11, wherein each of the first through part and the second through part includes:
a first metal layer; and
a second metal layer disposed on the first metal layer and including a metal material different from the first metal layer.

23. The circuit board of claim 22, wherein a lower surface of the first metal layer of each of the first and second through parts includes a convex portion recessed toward a lower surface of the build-up insulating layer.

24. The circuit board of claim 18, further comprising:
first and second semiconductor devices disposed on the first and second electrode parts,
wherein the first electrode part includes first electrode parts of a first group connected to a terminal of the first semiconductor device and first electrode parts of a second group connected to a terminal of the second semiconductor device, and
wherein the second electrode part includes second electrode parts of a first group connected to a terminal of the first semiconductor device and second electrode parts of a second group connected to a terminal of the second semiconductor device.

25. The circuit board of claim 24, wherein the second through part of at least one of the second electrode parts of the first group and the second group includes a plurality of sub-through parts vertically overlapped with a single protruding part and horizontally spaced apart from each other.

26. The circuit board of claim 25, wherein an upper surface of the single protruding part that is vertically overlapped with the plurality of sub-through parts includes a concave portion recessed toward each of the plurality of sub-through parts.
